(19) United States
(12) Patent Application Publication
(10) Pub. No.: US 2025/0098483 A1
(43) Pub. Date: Mar. 20, 2025

(54) DISPLAY PANEL AND PREPARATION METHOD THEREFOR, AND DISPLAY DEVICE

(71) Applicants: Hefei BOE Joint Technology Co., Ltd., Hefei (CN); BOE Technology Group Co., Ltd., Beijing (CN); Beijing BOE Technology Development Co., Ltd., Beijing (CN)

(72) Inventors: Xinxin WANG, Beijing (CN); Xiang WAN, Beijing (CN); Xinyu LI, Beijing (CN); Cheng XU, Beijing (CN); Dandan ZHOU, Beijing (CN); Ningning WANG, Beijing (CN)

(73) Assignees: Hefei BOE Joint Technology Co., Ltd., Hefei, AH (CN); BOE Technology Group Co., Ltd., Beijing (CN); Beijing BOE Technology Development Co., Ltd., Beijing (CN)

(21) Appl. No.: 18/291,592

(22) PCT Filed: Apr. 17, 2023
(86) PCT No.: PCT/CN2023/088606

§ 371 Date: Jan. 24, 2024

(51) Int. Cl. H10K 59/80; H10K 102/00

(52) U.S. Cl. CPC H10K 59/873; H10K 2102/341

(57) ABSTRACT

Provided is a display panel. The display panel includes a base substrate, a first electrode, a light-emitting layer, a protective layer, and a second electrode which are sequentially laminated on a side of the base substrate. A side of the light-emitting layer away from the base substrate is embedded with a target particle, and a gap in communication with the side of the light-emitting layer away from the base substrate is defined between the light-emitting layer and the target particle. The protective layer at least includes a first portion insulated from both the first electrode and the second electrode. The first portion fills the gap.

### CROSS-REFERENCE TO RELATED APPLICATION

The present disclosure is a U.S. national stage of international application No. PCT/CN2023/088606, filed on Apr. 17, 2023, the content of which is herein incorporated by reference in its entirety.

### TECHNICAL FIELD

The present disclosure relates to the field of display technologies, and in particular, to a display panel and a preparation method thereof, and a display device.

### BACKGROUND

With the advantages of self-illumination, low driving voltage, fast response, and the like, organic light-emitting diode (OLED) display panels are widely used.

### SUMMARY

The present disclosure provides a display panel and a preparation method therefor, and a display device. The technical solutions are as follows.

According to some embodiments of the present disclosure, a display panel is provided. The display panel includes: a base substrate, and a first electrode, a light-emitting layer, a protective layer, and a second electrode which are sequentially laminated on a side of the base substrate; wherein
a side of the light-emitting layer away from the base substrate is embedded with a target particle, and a gap in communication with the side of the light-emitting layer away from the base substrate is defined between the light-emitting layer and the target particle; and
the protective layer at least includes a first portion insulated from both the first electrode and the second electrode, wherein the first portion fills the gap.

In some embodiments, the target particle protrudes from a surface of the light-emitting layer away from the base substrate, and for a portion of the target particle which is embedded in the light-emitting layer, an orthographic projection of a side of the portion close to the base substrate onto the base substrate is within an orthographic projection of a side of the portion away from the base substrate onto the base substrate; and the protective layer further includes a second portion outside the gap;

the first portion is made of an oxide of a first material, and the second portion is made of a second material; and the first material is unable to be evaporated on the second material.

In some embodiments, the first material is magnesium and the second material is hydroxyquinolinolato-lithium.

In some embodiments, the protective layer further includes a second portion outside the gap; wherein the second portion and the first portion are an integral structure.

In some embodiments, a number of oxygen vacancies in the protective layer is less than a number of oxygen vacancies in the second electrode.

In some embodiments, a film layer density of the protective layer is greater than a film layer density of the second electrode.

In some embodiments, the first portion and the second portion are both made of an inorganic material.

In some embodiments, a thickness of the first portion in a direction perpendicular to the base substrate ranges from 2 nm to 5 nm.

In some embodiments, the inorganic material is at least one of silicon oxide, silicon nitride, and silicon nitride oxide.

In some embodiments, the first portion and the second portion of the protective layer both include a first sub-layer and a second sub-layer which are sequentially laminated in a direction going away from the base substrate; wherein

impedance of the second sub-layer is greater than impedance of the first sub-layer and is greater than impedance of the second electrode.

In some embodiments, a number of oxygen vacancies in the second sub-layer is less than a number of oxygen vacancies in the first sub-layer and is less than a number of oxygen vacancies in the second electrode.

In some embodiments, a film layer density of the second sub-layer is greater than a film layer density of the second electrode and is greater than a film layer density of the first sub-layer.

In another aspect, a method for preparing a display panel is provided. The method includes:
acquiring a base substrate; and
forming a first electrode, a light-emitting layer, a protective layer, and a second electrode sequentially on a side of the base substrate;
wherein a side of the light-emitting layer away from the base substrate is embedded with a target particle, and a gap in communication with the side of the light-emitting layer away from the base substrate is defined between the light-emitting layer and the target particle; and
wherein the protective layer at least includes a first portion insulated from both the first electrode and the second electrode, wherein the first portion fills the gap.

In some embodiments, the target particle protrudes from a surface of the light-emitting layer away from the base substrate, and for a portion of the target particle which is embedded in the light-emitting layer, an orthographic projection of a side of the portion close to the base substrate onto the base substrate is within an orthographic projection of a side of the portion away from the base substrate onto the base substrate; and forming the protective layer includes:
evaporating a second material on the side of the light-emitting layer away from the base substrate to form a second portion of the protective layer, wherein the second portion fractures at the gap;
evaporating a first material in the gap; and
performing an oxidation treatment on the first material to acquire the first portion of the protective layer;
wherein the second material is unable to be evaporated in a region where the first material is formed.

In some embodiments, forming the protective layer and the second electrode includes:
forming the first portion and a second portion of the protective layer when an oxygen concentration in a reaction chamber is a first concentration, wherein the second portion is outside the gap; and
forming the second electrode when the oxygen concentration in the reaction chamber is a second concentration;
wherein the first concentration is greater than the second concentration.

In some embodiments, the first concentration is greater than 4 volume flow rates, and the second concentration is less than 1 volume flow rate.

In some embodiments, forming the protective layer includes:

forming the first portion and a second portion of the protective layer by using an inorganic material on the side of the light-emitting layer away from the base substrate, wherein the second portion is outside the gap.

In some embodiments, forming the protective layer and the second electrode includes:
forming a first sub-layer when an oxygen concentration in a reaction chamber is a third concentration;
forming a second sub-layer when the oxygen concentration in the reaction chamber is a fourth concentration, wherein a portion of the second sub-layer and a portion of the first sub-layer which fill the gap form the first portion of the protective layer, and a portion of the second sub-layer and a portion of the first sub-layer which are outside the gap form a second portion of the protective layer; and
forming the second electrode when the oxygen concentration in the reaction chamber is a fifth concentration;
wherein the fourth concentration is greater than the third concentration and is greater than the fifth concentration.

In some embodiments, the third concentration and the fifth concentration are both less than 1 volume flow rate, and the fourth concentration is greater than 4 volume flow rates.

According to some embodiments of the present disclosure, a display device is provided. The display device includes: a power supply assembly, and the display panel as described in the above aspect; wherein the power supply assembly is configured to supply power to the display panel.

### BRIEF DESCRIPTION OF DRAWINGS

For a clearer description of the technical solutions in the embodiments of the present disclosure, the following briefly introduces the accompanying drawings required for describing the embodiments. The accompanying drawings in the following descriptions show merely some embodiments of the present disclosure, and persons of ordinary skill in the art may still derive other drawings from these accompanying drawings without creative effort.

FIG. 1 is a schematic structural diagram of a display panel according to some embodiments of the present disclosure;

FIG. 2 is a schematic structural diagram of another display panel according to embodiments of the present disclosure;

FIG. 3 is a schematic diagram of a dark spot according to some embodiments of the present disclosure;

FIG. 4 is a curve graph of a relationship between a wavelength and transmittance according to some embodiments of the present disclosure;

FIG. 5 is a curve graph of a relationship between oxygen concentration and resistance according to some embodiments of the present disclosure;

FIG. 6 is an electron microscope diagram of a display panel according to some embodiments of the present disclosure;

FIG. 7 is an electron microscope diagram of another display panel according to embodiments of the present disclosure;

FIG. 8 is a schematic diagram of film layers of a display panel according to some embodiments of the present disclosure;

FIG. 9 is a schematic structural diagram of yet another display panel according to embodiments of the present disclosure;

FIG. 10 is a flowchart of a method for preparing a display panel according to some embodiments of the present disclosure;

FIG. 11 is a flowchart of another method for preparing a display panel according to some embodiments of the present disclosure;

FIG. 12 is a schematic diagram of formation of a light-emitting layer according to some embodiments of the present disclosure;

FIG. 13 is a schematic diagram of formation of a second portion of a protective layer according to some embodiments of the present disclosure;

FIG. 14 is a schematic diagram of formation of a first material by evaporation in a gap between a target particle and a light-emitting layer according to some embodiments of the present disclosure;

FIG. 15 is a flowchart of yet another method for preparing a display panel according to embodiments of the present disclosure;

FIG. 16 is a flowchart of still another method for preparing a display panel according to embodiments of the present disclosure;

FIG. 17 is a flowchart of still another method for preparing a display panel according to embodiments of the present disclosure; and

FIG. 18 is a schematic structural diagram of a display device according to some embodiments of the present disclosure.

### DETAILED DESCRIPTION

To make the objectives, technical solutions and advantages of the present disclosure clearer, the embodiments of the present disclosure will be further described in detail below with reference to the accompanying drawings.

In the related technology, an OLED device in an OLED display panel generally includes an anode, a light-emitting layer, and a cathode. The light-emitting layer is made of an organic semiconductor material and can emit light under the drive of the anode and the cathode.

However, during the process of preparing the OLED display panel, particles are easily embedded in the light-emitting layer, and when the cathode is formed, the cathode material easily penetrates towards the anode along a gap between the particles and the light-emitting layer, which leads to a short-circuit of the anode and the cathode. Thus, the yield of the OLED display panel is lower, and the display effect of the display device is poor.

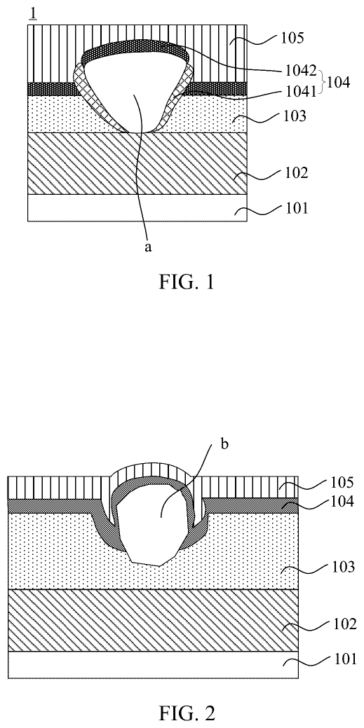

FIG. 1 is a schematic structural diagram of a display panel 1 according to some embodiments of the present disclosure. Referring to FIG. 1, the display panel 1 includes a base substrate 101, and a first electrode 102, a light-emitting layer 103, a protective layer 104, and a second electrode 105 which are sequentially laminated on a side of the base substrate 101. A target particle a is embedded in the side of the light-emitting layer 103 away from the base substrate 101, and a gap in communication with the side of the light-emitting layer 103 away from the base substrate 101 is defined between the light-emitting layer 103 and the target particle a. In FIG. 1, the gap is not only in communication with the side of the light-emitting layer 103 away from the base substrate 101 but also in communication with the side of the light-emitting layer 103 close to the base substrate 101. That is, in FIG. 2, one side of the target particle a is in contact with the first electrode 102, and the other side of the target particle a protrudes from the surface of the light-emitting layer 103 away from the base substrate 101. The first electrode 102 is an anode, and the second electrode 105 is a cathode.

Referring to FIG. 1, the protective layer 104 at least includes a first portion 1041 that is insulated from both the first electrode 102 and the second electrode 105. In some embodiments, the impedance of the first portion 1041 is greater than an impedance threshold. The impedance threshold is big enough such that the first portion 1041 does not have a conductive property, but rather an insulating property.

Furthermore, since the first portion 1041 fills the gap between the light-emitting layer 103 and the target surface particle a, when the second electrode 105 is formed, the second electrode 105 does not penetrate to the first electrode 102 along the gap, which can avoid the short-circuit of the second electrode 105 and the first electrode 102 caused by contact.

Since the first portion 1041 is insulated from both the first electrode 102 and the second electrode 105, even if the upper end of the first portion 1041 is in contact with the second electrode 105 and the lower end of the first portion 1041 is in contact with the first electrode 102, the first electrode 102 and the second electrode 105 will not be electrically connected by the first portion 1041, thereby avoiding the short-circuit. Thus, by filling the gap between the target particle a and the light-emitting layer 103 with the first portion 1041 of the protective layer 104, the short-circuit of the first electrode 102 and the second electrode 105 can be avoided, thereby ensuring the yield of the display panel 1 and the display effect of the display device.

In summary, the embodiments of the present disclosure provide a display panel, including a base substrate, and a first electrode, a light-emitting layer, a protective layer, and a second electrode which are sequentially laminated on a side of the base substrate. Due to the influence of the preparation process of the display panel, a target particle is easily embedded in the light-emitting layer, and a gap in communication with the side of the light-emitting layer away from the base substrate is formed between the embedded target particle and the light-emitting layer. The first portion of the protective layer which is insulated from the first electrode and the second electrode fills the gap, which can prevent the formed second electrode from penetrating to the first electrode along the gap, and thus can avoid the short-circuit of the first electrode and the second electrode. Therefore, the yield of the display panel and the display effect of the display device are ensured.

In the embodiments of the present disclosure, in addition to the first portion 1041 filling the gap, the protective layer 104 further includes a second portion 1042 outside the gap. That is, the second portion 1042 is disposed on the side of the target particle a away from the base substrate 101, or disposed on the side of the light-emitting layer 103 which is not embedded with the target particle a and is away from the base substrate 101. In this way, the electrons generated by the second electrode 105 are transmitted to the light-emitting layer 103 through the second portion 1042, and the electrons are combined with the holes generated by the first electrode 102 in the light-emitting layer 103, thereby emitting light. The second portion 1042 of the protective layer 104 acts as an electron transport layer.

It should be noted that the light-emitting layer 103 also has other particles therein in addition to the target particle a shown in FIG. 1. In some embodiments, referring to FIG. 2, the light-emitting layer 103 also has a first type of particles that are not in contact with the first electrode 102 but protrude from the surface of the light-emitting layer 103 away from the base substrate 101; a second type of particles that are in contact with the first electrode 102 but do not protrude from the surface of the light-emitting layer 103 away from the base substrate 101; and a third type of particles that are not in contact with the first electrode 102 and do not protrude from the surface of the light-emitting layer 103 away from the base substrate 101 (i.e., wrapped within the light-emitting layer 103).

For the first type of particles described above, the particle b is not in contact with the first electrode 102, and thus the gap between the particle and the light-emitting layer 103 is not in communication with the side of the light-emitting layer 103 close to the base substrate 101, that is, the gap does not extend to the surface of the first electrode 102. However, by filling the gap between the particle and the light-emitting layer 103 with the first portion 1041, the short-circuit of the first electrode 102 and the second electrode 105 can be further avoided.

For the second type of particles and the third type of particles described above, since the particles do not protrude from the surface of the light-emitting layer 103 away from the base substrate 101, at the positions of the two particles, the particles are not in communication with the side of the light-emitting layer 103 away from the base substrate 101. Therefore, in the regions where the two particles are located, the second portion 1042 of the protective layer 104 is provided on the side of the light-emitting layer 103 away from the base substrate 101.

In some embodiments, the first material for forming the first portion 1041 has a non-coevaporation property with the second material for forming the second portion 1042. The non-coevaporation property refers to that the second material cannot be formed by evaporation in a region where the first material is formed by evaporation. The first portion 1041 is made of an oxide of the first material, and the second portion 1042 is made of the second material.

In some embodiments, the process of forming the protective layer 104 includes: forming the second portion 1042 made of the second material on the side of the light-emitting layer 103 away from the base substrate 101 by an evaporation process, wherein the second portion 1042 is not disposed in the gap between the target particle a and the light-emitting layer 103; filling the gap between the target particle a and the light-emitting layer 103 with the first material by the evaporation process; and performing an oxidation treatment on the first material formed in the gap to acquire an oxide of the first material having a conductivity less than a conductivity threshold (e.g., the oxide of the first material is a non-conductive oxide). The non-conductive oxide of the first material can block the second electrode 105 from penetrating along the gap between the target particle a and the light-emitting layer 103, to avoid the formation of dark spots caused by the short-circuit of the first electrode 102 and the second electrode 105 in the lighting process of the display panel 1. Thus, the display effect of the display device is better.

In order that the second material fractures at the edge of the target particle a when the second material is formed by evaporation to expose the gap between the target particle a and the light-emitting layer 103, there are certain requirements on the target particle a. In some embodiments, the requirements are as follows: the target particle a protrudes from the surface of the light-emitting layer 103 away from the base substrate 101, and for the portion of the target particle a embedded in the light-emitting layer 103, the orthographic projection of the side of the portion close to the base substrate 101 onto the base substrate 101 is within the orthographic projection of the side of the portion away from the base substrate 101 onto the base substrate 101.

Furthermore, the second material has poor continuity. Therefore, since the target particle a protrudes from the surface of the light-emitting layer 103, the second material fractures at the edge of the target particle a. As a result, the second material does not fill the gap between the target particle a and the light-emitting layer 103, whereas the first material fills the gap based on the non-coevaporation property of the second material and the first material.

Additionally, the second portion 1042 made of the second material acts as an electron injection layer for the second electrode 105, and the second portion 1042 is configured to avoid damage to the light-emitting layer 103 during the process of forming the second electrode 105 by a sputtering process, that is, the second portion 1042 is a damage-resisting layer for the light-emitting layer 103.

In some embodiments, the first material is magnesium (Mg), that is, the first portion 1041 is made of magnesium oxide (MgO); and the second material is hydroxyquinolinolato-lithium (LiQ), that is, the second portion 1042 is made of LiQ.

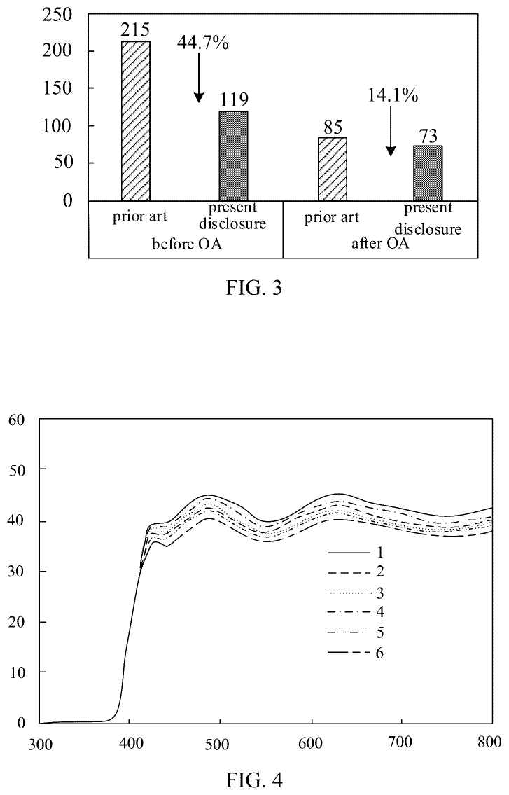

Taking a display panel (55-inch) in some practices and a display panel (55-inch) in some embodiments of the present disclosure as an example, referring to FIG. 3, before the display panel is powered on (OAging, OA), the number of dark dots in the display panel in some practices is 215, and the number of dark dots in the display panel in some embodiments of the present disclosure is 119. The number of dark dots in the solution of the embodiments of the present disclosure is reduced by 44.7% compared to that in the solution of some practices. After the display panel is powered on (OA), the number of dark dots in the display panel in some practices is 85, and the number of dark dots in the display panel in some embodiments of the present disclosure is 73. The number of dark dots in the solution of the embodiments of the present disclosure is reduced by 14.1% compared to that in the solution of some practices. That is, according to the solution provided in the embodiments of the present disclosure, the number of dark spots can be reduced, and the display effect of the display panel can be improved. Here, OA refers to that the display panel is powered on in atmosphere before being packaged.

Furthermore, the transmittance of the display panel (55-inch) in some practices and the transmittance of the display panel (55-inch) in some embodiments of the present disclosure are detected. As can be seen from FIG. 4 and Table 1 below, for the display panel in some practices, its transmittance of light having a wavelength of 550 nanometers (nm) is 38.83%, while for the display panel in the embodiments of the present disclosure, its transmittance of light having a wavelength of 550 nm is 37.30%. That is, the transmittance of light having a wavelength of 550 nm in the solution of the present disclosure embodiment is decreased by 1.53% compared to that in the solution of some practices. Meanwhile, for the display panel in some practices, its average transmittance of visible light waveband is 38.8%, while for the display panel in the embodiments of the present disclosure, its average transmittance of visible light waveband is 37.3%. That is, the average transmittance of visible light waveband is decreased by 1.50% in the solution of the embodiments of the present disclosure compared to that in the solution of some practices.

Therefore, the solution of the display panel in the embodiments of the present disclosure has a small influence on the transmittance compared to the solution in some practices. In FIG. 4, the horizontal coordinate represents the wavelength (nm), and the vertical coordinate represents the transmittance (%). Curves 1, 2 and 3 are transmittance curves of the display panel tested at different positions thereof in some practices, and curves 4, 5 and 6 are transmittance curves of the display panel tested at different positions thereof in the embodiments of the present disclosure.

TABLE 1

| | Some | Embodiments of the | |
|---|---|---|---|
| Transmittance | practices | present disclosure | Difference |
| 550 nm | 38.83% | 37.30% | −1.53% |
| Visible light waveband | 38.80% | 37.30% | −1.50% |

In some embodiments, the second portion 1042 and the first portion 1041 of the protective layer 104 are an integral structure. In some embodiments, the second portion 1042 and the first portion 1041 of the protective layer 104 are made of the same material. Since the first portion 1041 is insulated from both the first electrode 102 and the second electrode 105, the second portion 1042 is also insulated from both the first electrode 102 and the second electrode 105. That is, the impedance of the second portion 1042 is also greater than the impedance threshold (which is big enough). Generally, the impedance of the second electrode 105 is less than the impedance threshold, that is, the impedance of the protective layer 104 is greater than the impedance of the second electrode 105.

Since the protective layer 104 with higher impedance is disposed between the light-emitting layer 103 and the second electrode 105, the protective layer 104 with higher impedance can first penetrate into the gap between the light-emitting layer 103 and the target particle a, and thus the second electrode 105 and the first electrode 102 have a large resistance therebetween. Therefore, the second electrode 105 and the first electrode 102 are not easily short-circuited.

In some embodiments, the impedance of the protective layer 104 being greater than the impedance threshold refers to that the surface resistance of the protective layer 104 is greater than ninth power of ten (10⁹).

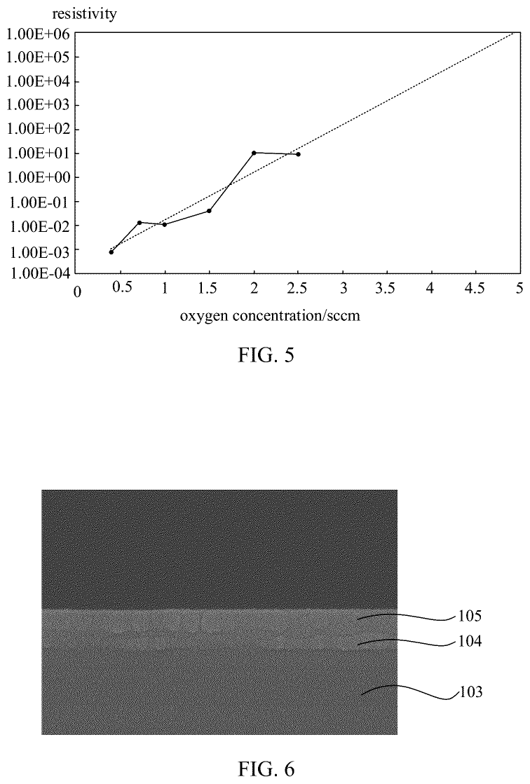

In the embodiments of the present disclosure, as can be seen from FIG. 5, the impedance of the formed film layer is positively correlated with the oxygen concentration in the reaction chamber. That is, the higher the oxygen concentration in the reaction chamber, the smaller the number of oxygen vacancies in the formed film layer, and the higher the impedance of the formed film layer. The lower the oxygen concentration in the reaction chamber, the larger the number of oxygen vacancies in the formed film layer, and the lower the impedance of the formed film layer. Therefore, in order to obtain the protective layer 104 with higher impedance, the most direct preparation method is to increase the oxygen concentration in the reaction chamber. Increasing the oxygen concentration in the reaction chamber makes the protective layer 104 have fewer oxygen vacancies during film formation, which can increase the impedance of the protective layer 104.

In the embodiments of the present disclosure, the number of oxygen vacancies in the protective layer 104 is less than the number of oxygen vacancies in the second electrode 105. The protective layer 104 is obtained by a first preparation process in the reaction chamber, and the second electrode 105 is obtained by a second preparation process in the reaction chamber. The oxygen concentration during the first preparation process in the reaction chamber is greater than the oxygen concentration during the second preparation process in the reaction chamber.

In some embodiments, the protective layer 104 and the second electrode 105 are made of the same material, and are only different in impedance. In some embodiments, the protective layer 104 and the second electrode 105 are both made of indium zinc oxide (IZO). The impedance of the protective layer 104 is greater than the impedance of the second electrode 105.

Certainly, the protective layer 104 and the second electrode 105 are also made of different materials. In some embodiments, the protective layer 104 is made of another oxide material with a surface resistance greater than 10⁹, such as zinc oxide (ZnOx) or indium oxide (InOx). Moreover, the preparation process of the protective layer 104 is not limited to the sputtering process, and other processes, such as an atomic layer deposition (ALD) process, are also adopted.

In FIG. 5, the horizontal coordinate represents the oxygen concentration (sccm) and the vertical coordinate represents the resistivity of the film layer (ohm cm/Ω·cm). The surface resistance of the film layer is equal to the resistivity divided by the thickness of the film layer. FIG. 5 shows a curve graph for a film layer with a thickness of, in some embodiments, 1000 A (Angstrom). In FIG. 5, the solid line represents experimental data, and the dashed line represents a simulation curve obtained based on the experimental data. Provided that the thickness of the film layer is converted to a unit of centimeters, it is calculated that the resistivity of the protective layer 104 needs to reach 1.00E+04 (i.e., 1×10⁴) in order that the surface resistance of the protective layer 104 reaches 10⁹. Referring to FIG. 5, it can be seen that the oxygen concentration in the reaction chamber needs to be greater than 4 sccm (volume flow rate) during the first preparation process. In addition, in order to make the impedance of the second electrode 105 smaller, the oxygen concentration in the reaction chamber during the second preparation process is less than 1 sccm, In some embodiments, about 0.5 sccm. Also, in FIG. 5, 1.00E-04 represents 1×10⁻⁴, and so on for the others, which are not repeated herein.

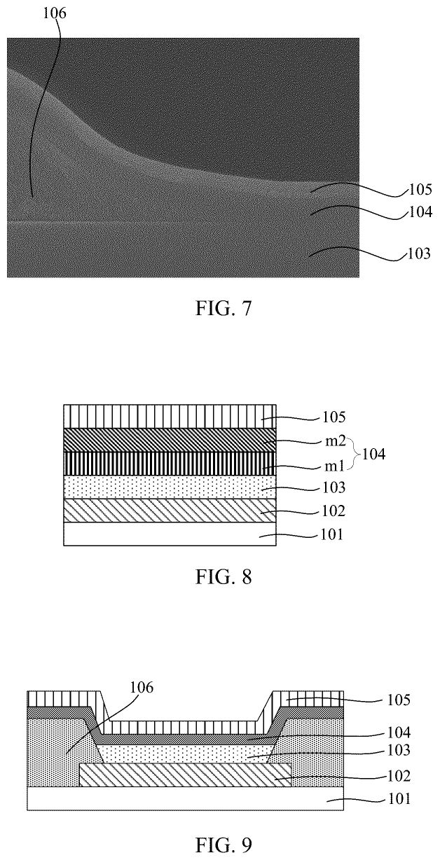

With reference to FIG. 6 and FIG. 7, the protective layer 104 and the second electrode 105 can be generally distinguished, and the protective layer 104 has a denser film layer than the second electrode 105, that is, the film layer density of the protective layer 104 is greater than the film layer density of the second electrode 105. In some embodiments, the thickness of the protective layer 104 ranges from 300 A to 600 A, and the thickness of the second electrode 105 ranges from 300 A to 400 A. That is, the total thickness of the protective layer 104 and the second electrode 105 ranges from 600 A to 1000 A.

By experimentally verifying the display panel 1 of the second implementation, it is found that the improvement ratio of the dark points according to this solution is roughly 40% to 60%, i.e., the number of the display dark points of the display panel 1 can be reduced by more than a half. In addition, in order to improve the display dark spots of the display panel 1 more effectively, the packaging film layer of the display panel 1 is prepared by a hydrogen-free chemical vapor deposition (CVD) process, which can prevent the hydrogen ions from taking oxygen away from the protective layer 104 to lead to an increase in the oxygen vacancies in the protective layer 104, and thus can avoid the decrease in the surface resistance of the protective layer 104 due to the increase in the oxygen vacancies in the protective layer 104. Additionally, when the display panel 1 is subsequently baked, the baking temperature is lower than 80° C. (degrees Celsius) and the baking duration is less than 30 min (minutes), and an ultraviolet (UV)-type filler adhesive is preferred.

In some embodiments, the second portion 1042 and the first portion 1041 of the protective layer 104 are an integral structure. In some embodiments, the first portion 1041 and the second portion 1042 of the protective layer 104 are made of an inorganic material. Since the protective layer 104 made of the inorganic material is disposed between the light-emitting layer 103 and the second electrode 105, the protective layer 104 made of the inorganic material first penetrates into the gap between the light-emitting layer 103 and the target particle a to insulate the second electrode 105 from the first electrode 102, thereby avoiding the short-circuit of the second electrode 105 and the first electrode 102.

The thickness of the first portion 1041 of the protective layer 104 in the direction perpendicular to the base substrate 101 ranges from 2 nm to 5 nm, that is, the protective layer 104 is not too thick or too thin. Therefore, the protective layer 104 can have an insulating effect, and can also facilitate the injection of electrons generated by the second electrode 105 into the light-emitting layer 103 through tunneling to ensure the effective light emission of the display panel 1.

In some embodiments, the inorganic material is at least one of silicon oxide, silicon nitride, and silicon nitride oxide. The inorganic material is prepared by a CVD process, and the protective layer 104 prepared by the CVD process has a strong gap penetrating capability and can effectively fill the gap between the target particle a and the light-emitting layer 103.

In some embodiments, the second portion 1042 and the first portion 1041 of the protective layer 104 are an integral structure. Referring to FIG. 8, the protective layer 104 includes a first sub-layer m1 and a second sub-layer m2 sequentially laminated in the direction going away from the base substrate 101. The impedance of the material of second sub-layer m2 is greater than the impedance of the material of the first sub-layer m1 and greater than the impedance of the material of the second electrode 105. In this implementation, the portion of the first sub-layer m1 and the portion of the second sub-layer m2 which fill the gap form the first portion 1041 of the protective layer 104, and the portion of the first sub-layer m1 and the portion of the second sub-layer m2 which are outside the gap form the second portion 1042 of the protective layer 104.

In this implementation, the protective layer 104 and the second electrode 105 form a sandwich structure of low resistance, high resistance, and low resistance. In this way, the first sub-layer m1 with a lower impedance in the protective layer 104 is in direct contact with the electron transport layer in the light-emitting layer 103, which can ensure the transmission effect of the electrons generated by the second electrode 105.

In some embodiments, the thickness of the first sub-layer m1 ranges from 50 A to 100 A, that is, the first sub-layer m1 is relatively thin and does not fill up the gap between the target particle a and the light-emitting layer 103. By providing the second sub-layer m2 with higher impedance on the side of the first sub-layer m1 away from the base substrate 101, the second sub-layer m2 with higher impedance fills up the gap, which can avoid the short-circuit of the second electrode 105 and the first electrode 102.

In this implementation, the impedance of the second sub-layer m2 is greater than the impedance threshold. The impedance of the second sub-layer m2 being greater than the impedance threshold refers to that the surface resistance of the protective layer 104 is greater than the ninth power of ten (10⁹).

With reference to FIG. 5, with the increase of the oxygen concentration in the reaction chamber, the number of the oxygen vacancies in the prepared film layer decreases, and the impedance of the film layer increases. Thus, in order to obtain the second sub-layer m2 with high impedance, the most direct method is to increase the oxygen concentration in the reaction chamber. Increasing the oxygen concentration in the reaction chamber makes the second sub-layer m2 have fewer oxygen vacancies during film formation, which can increase the impedance of the second sub-layer m2.

The first sub-layer m1 is obtained by a third preparation process in the reaction chamber, the second sub-layer m2 is obtained by a fourth preparation process in the reaction chamber, and the second electrode 105 is obtained by a fifth preparation process in the reaction chamber. The oxygen concentration during the fourth preparation process in the reaction chamber is greater than the oxygen concentration during the third preparation process in the reaction chamber and greater than the oxygen concentration during the fifth preparation process in the reaction chamber. Therefore, the number of the oxygen vacancies in the second sub-layer m2 is less than the number of the oxygen vacancies in the first sub-layer m1 and less than the number of the oxygen vacancies in the second electrode 105.

As can be seen from FIG. 5, in order to make the surface resistance of the second sub-layer m2 reach 10⁹, the oxygen concentration in the reaction chamber during the fourth preparation process needs to be greater than 4 sccm. In addition, in order to make the impedance of the first sub-layer m1 and the impedance of the second electrode 105 smaller, the oxygen concentrations in the reaction chamber during the third preparation process and the fifth preparation process are less than 1 sccm, in some embodiments, about 0.5 sccm.

The film layer density of the second sub-layer m2 is greater than the film layer density of the first sub-layer m1 and greater than the film layer density of the second electrode 105. The thickness of the second sub-layer m2 ranges from 200 A to 500 A. The total thickness of the protective layer 104 and the second electrode 105 ranges from 800 A to 1500 A.

In order to improve the display dark spots of the display panel 1 more effectively, the packaging film layer of the display panel 1 is prepared by a hydrogen-free CVD process, which can prevent the hydrogen ions from taking oxygen away from the protective layer 104 to lead to an increase in the oxygen vacancies in the protective layer 104, and thus can avoid the decrease in the surface resistance of the protective layer 104 due to the increase in the oxygen vacancies in the protective layer 104.

In some embodiments, the first sub-layer m1, the second sub-layer m2 and the second electrode 105 are made of the same material, and are only different in impedance. In some embodiments, the first sub-layer m1, the second sub-layer m2 and the second electrode 105 are all made of IZO.

Certainly, the second sub-layer m2 and the second electrode 105 are also made of different materials. In some embodiments, the second sub-layer m2 is made of another oxide material with a surface resistance greater than 10⁹, such as ZnOx or InOx. Moreover, the preparation process of the second sub-layer m2 is not limited to the sputtering process, and other processes, such as an atomic layer deposition (ALD) process, are also adopted

Since the impedance of the first sub-layer m1 and the impedance of the second electrode 105 are both low, in order to simplify the preparation process, the first sub-layer m1 and the second electrode 105 are made of the same material and prepared by the same preparation process. In some embodiments, the material is IZO and the preparation process is the sputtering process.

Referring to FIG. 9, the display panel 1 further includes a pixel defining layer 106. The pixel defining layer 106 is disposed on the side of the first electrode 102 away from the base substrate 101, and the pixel defining layer 106 has a hollowed-out area. The hollowed-out area is configured to expose the first electrode 102 such that the light-emitting layer 103 is in contact with the first electrode 102, thereby ensuring the normal display of the display panel 1.

In summary, the embodiments of the present disclosure provide a display panel, including a base substrate, and a first electrode, a light-emitting layer, a protective layer, and a second electrode which are sequentially laminated on a side of the base substrate. Due to the influence of the preparation process of the display panel, a target particle is easily embedded in the light-emitting layer, and a gap in communication with the side of the light-emitting layer away from the base substrate is formed between the embedded target particle and the light-emitting layer. The first portion of the protective layer which is insulated from the first electrode and the second electrode fills the gap, which can prevent the formed second electrode from penetrating to the first electrode along the gap, and thus can avoid the short-circuit of the first electrode and the second electrode. Therefore, the yield of the display panel and the display effect of the display device are ensured.

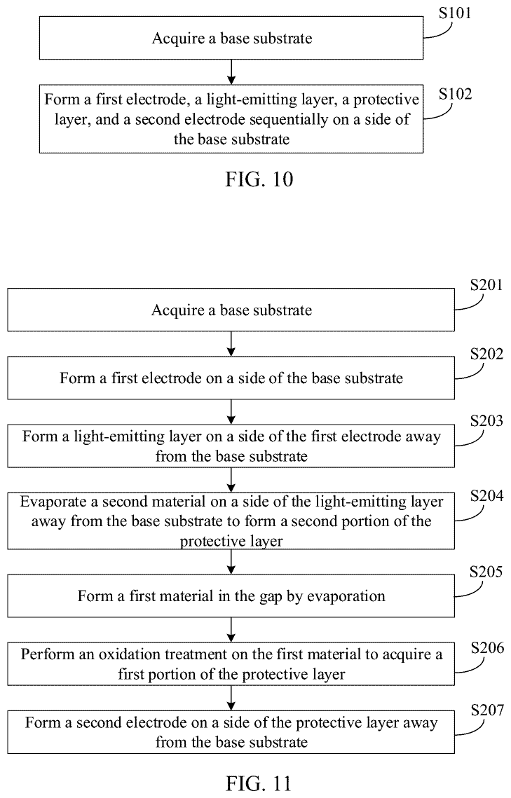

FIG. 10 is a flowchart of a method for preparing a display panel according to some embodiments of the present disclosure. Referring to FIG. 10, the method includes the following steps.

In step S101, a base substrate is acquired.

In the embodiments of the present disclosure, a base substrate 101 is acquired first when the display panel 1 is prepared. The base substrate 101 is a glass substrate or a flexible substrate. The flexible substrate is made of polyimide (PI).

In step S102, a first electrode, a light-emitting layer, a protective layer, and a second electrode are sequentially formed on a side of the base substrate.

After the base substrate 101 is acquired, the first electrode 102, the light-emitting layer 103, the protective layer 104, and the second electrode 105 are sequentially formed on a side of the base substrate 101. In the process of preparing the light-emitting layer 103, due to the influence of the preparation process, the side of the light-emitting layer 103 away from the base substrate 101 is embedded with a target particle a, and a gap in communication with the side of the light-emitting layer 103 away from the base substrate 101 is defined between the light-emitting layer 103 and the target particle a.

In the embodiments of the present disclosure, after the light-emitting layer 103 is formed, the protective layer 104 is formed first, and then the second electrode 105 is formed. In this way, a first portion 1041 of the protective layer 104 which is insulated from both the first electrode 102 and the second electrode 105 fills the gap. In some embodiments, the impedance of the first portion 1041 is greater than an impedance threshold. The impedance threshold is big enough such that the first portion 1041 does not have a conductive property, but rather an insulating property.

Furthermore, since the first portion 1041 fills the gap between the light-emitting layer 103 and the target surface particle a, when the second electrode 105 is formed, the second electrode 105 does not penetrate to the first electrode 102 along the gap, which can avoid the short-circuit of the second electrode 105 and the first electrode 102 caused by contact.

Since the first portion 1041 is insulated from both the first electrode 102 and the second electrode 105, even if the upper end of the first portion 1041 is in contact with the second electrode 105 and the lower end of the first portion 1041 is in contact with the first electrode 102, the first electrode 102 and the second electrode 105 will not be electrically connected by the first portion 1041, thereby avoiding the short-circuit. Thus, by filling the gap between the target particle a and the light-emitting layer 103 with the first portion 1041 of the protective layer 104, the short-circuit of the first electrode 102 and the second electrode 105 can be avoided, thereby ensuring the yield of the display panel 1 and the display effect of the display device.

In summary, the embodiments of the present disclosure provide a method for preparing a display panel. The display panel prepared by this method includes a base substrate, and a first electrode, a light-emitting layer, a protective layer, and a second electrode which are sequentially laminated on a side of the base substrate. Due to the influence of the preparation process of the display panel, a target particle is easily embedded in the light-emitting layer, and a gap in communication with the side of the light-emitting layer away from the base substrate is formed between the embedded target particle and the light-emitting layer. The first portion of the protective layer which is insulated from the first electrode and the second electrode fills the gap, which can prevent the formed second electrode from penetrating to the first electrode along the gap, and thus can avoid the short-circuit of the first electrode and the second electrode. Therefore, the yield of the display panel and the display effect of the display device are ensured.

FIG. 11 is a flowchart of another method for preparing a display panel according to some embodiments of the present disclosure. Referring to FIG. 11, the method includes the following steps.

In step S201, a base substrate is acquired.

In the embodiments of the present disclosure, a base substrate 101 is acquired first when the display panel 1 is prepared. The base substrate 101 is a glass substrate or a flexible substrate. The flexible substrate is made of PI.

In step S202, a first electrode is formed on a side of the base substrate.

In the embodiments of the present disclosure, a first electrode film is formed on a side of the base substrate 101, and the first electrode film is patterned to acquire the first electrode 102. The first electrode 102 is an anode of a light-emitting element in the display panel 1. The patterning process includes: photoresist coating, exposure, development, etching, and photoresist stripping.

In step S203, a light-emitting layer is formed on a side of the first electrode away from the base substrate.

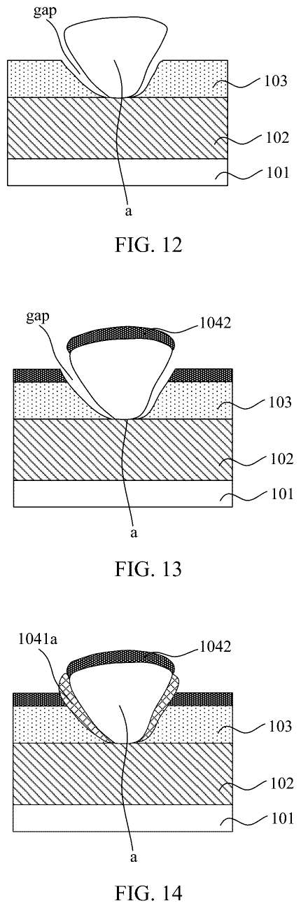

In the embodiments of the present disclosure, referring to FIG. 12, the light-emitting layer 103 is disposed on the side of the first electrode 102 away from the base substrate 101. The preparation process of the light-emitting layer 103 includes: forming a light-emitting film on the side of the first electrode 102 away from the base substrate 101; and patterning the light-emitting film to acquire the light-emitting layer 103.

Referring to FIG. 12, due to the influence of the preparation process of the light-emitting layer 103, a target particle a is embedded in the light-emitting layer 103. The target particle a protrudes from the surface of the light-emitting layer 103 away from the base substrate 101, and for the portion of the target particle a embedded in the light-emitting layer 103, the orthographic projection of the side of the portion close to the base substrate 101 onto the base substrate 101 is within the orthographic projection of the side of the portion away from the base substrate 101 onto the base substrate 101. Moreover, a gap in communication with the side of the light-emitting layer 103 away from the base substrate 101 is defined between the target particle a and the light-emitting layer 103.

In step S204, a second material is evaporated on a side of the light-emitting layer away from the base substrate to form a second portion of the protective layer.

In the embodiments of the present disclosure, referring to FIG. 13, the prepared second portion 1042 fractures at an edge of the target particle a (e.g., at the gap between the light-emitting layer 103 and the target particle a) due to the poor continuity of the second material. Therefore, the second material does not fill the gap between the target particle a and the light-emitting layer 103.

In some embodiments, the thickness of the second portion 1042 ranges from 5 nm to 10 nm.

In step S205, a first material is formed in the gap by evaporation.

In the embodiments of the present disclosure, the first material has a non-coevaporation property with the second material. The non-coevaporation property refers to that the first material cannot be formed by evaporation in a region where the second material is formed by evaporation.

Therefore, referring to FIG. 14, based on the non-co-evaporation property of the first material and the second material, the first material fills the gap between the light-emitting layer 103 and the target particle a.

In step S206, an oxidation treatment is performed on the first material to acquire a first portion of the protective layer.

In the embodiments of the present disclosure, an oxidation treatment is performed on the first material to acquire a non-conductive oxide of the first material. The non-conductive oxide of the first material can block the second electrode 105 which is formed later from penetrating along the gap between the light-emitting layer 103 and the target particle a, to avoid the formation of dark spots caused by the short-circuit of the first electrode 102 and the second electrode 105 which is formed later in the lighting process of the display panel 1. Thus, the display effect of the display device is ensured.

In step S207, a second electrode is formed on a side of the protective layer away from the base substrate.

In the embodiments of the present disclosure, a sputtering process is adopted to form the second electrode 105 on the side of the protective layer 104 away from the base substrate 101. The second electrode 105 is a cathode of a light-emitting element in the display panel 1. The second electrode 105 is made of IZO.

In some embodiments, the display panel 1 includes a plurality of light-emitting elements, and the cathodes of the plurality of light-emitting elements are a common film layer.

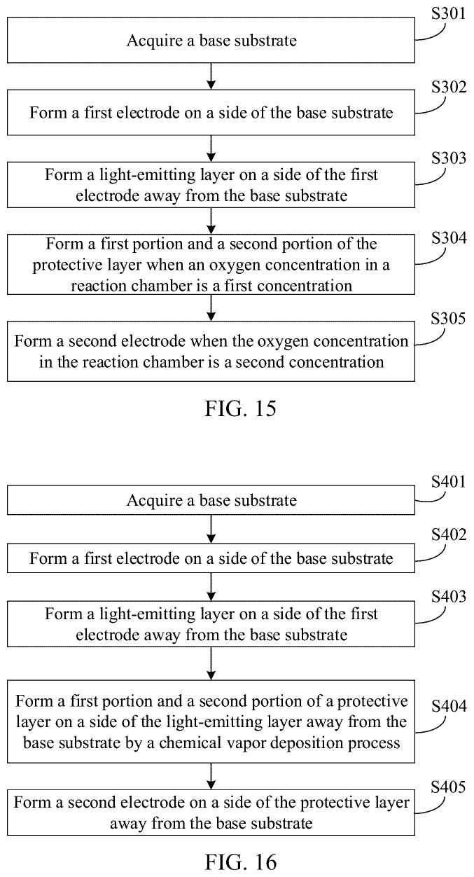

FIG. 15 is a flowchart of yet another method for preparing a display panel according to some embodiments of the present disclosure. Referring to FIG. 15, the method includes the following steps.

In step S301, a base substrate is acquired.

In step S302, a first electrode is formed on a side of the base substrate.

In step S303, a light-emitting layer is formed on a side of the first electrode away from the base substrate.

In the embodiments of the present disclosure, for the detailed description of steps S301 to S303, reference can be made to steps S201 to S203 described above, and the details are not repeated herein.

In step S304, a first portion and a second portion of the protective layer are formed when an oxygen concentration in a reaction chamber is a first concentration.

In the embodiments of the present disclosure, the second portion 1042 is outside a gap, in some embodiments, on the side of a target particle a away from the base substrate 101, and is on the side of the light-emitting layer 103 which is not embedded with the target particle a and is away from the base substrate 101.

The film layers of the display panel 1 are all prepared in the reaction chamber. Due to the increase of the oxygen concentration in the reaction chamber, the number of oxygen vacancies in the prepared film layer is smaller, and the impedance of the film layer is increased. Therefore, in order to acquire a protective layer 104 with higher impedance, the first concentration is made higher, in some embodiments, greater than 4 sccm.

Since the protective layer 104 with higher impedance is disposed between the light-emitting layer 103 and the second electrode 105, the protective layer 104 with higher impedance can first penetrate into the gap between the light-emitting layer 103 and the target particle a, and thus the second electrode 105 which is formed later and the first electrode 102 have a large resistance therebetween. Therefore, the second electrode 105 and the first electrode 102 are not easily short-circuited.

In some embodiments, the protective layer 104 is made of IZO, ZnOx or InOx, and the protective layer 104 is prepared by a sputtering process or an ALD process.

In step S305, a second electrode is formed when the oxygen concentration in the reaction chamber is a second concentration.

In the embodiments of the present disclosure, when the second electrode 105 is prepared, the oxygen concentration in the reaction chamber is lower (the second concentration is less than the first concentration), in some embodiments, less than 1 sccm.

The second electrode 105 is a cathode of a light-emitting element in the display panel 1. The second electrode 105 is made of IZO. In some embodiments, the second electrode 105 is prepared by a sputtering process, an ALD process, or the like.

In some embodiments, the display panel 1 includes a plurality of light-emitting elements, and the cathodes of the plurality of light-emitting elements are a common film layer.

FIG. 16 is a flowchart of still another method for preparing a display panel according to some embodiments of the present disclosure. Referring to FIG. 16, the method the following steps.

In step S401, a base substrate is acquired.

In step S402, a first electrode is formed on a side of the base substrate.

In step S403, a light-emitting layer is formed on a side of the first electrode away from the base substrate.

In the embodiments of the present disclosure, for the detailed description of steps S401 to S403, reference can be referred to steps S201 to S203 described above, and the details are not repeated herein.

In step S404, a first portion and a second portion of a protective layer are formed on a side of the light-emitting layer away from the base substrate by a chemical vapor deposition process (CVD).

The second portion 1042 is outside a gap, in some embodiments, on the side of a target particle a away from the base substrate 101, and is on the side of the light-emitting layer 103 which is not embedded with the target particle a and is away from the base substrate 101.

The first portion 1041 and the second portion 1042 of the protective layer 104 are an integral structure, and the protective layer 104 is made of an inorganic material. The protective layer 104 made of the inorganic material can penetrate into the gap between the light-emitting layer 103 and the target particles a, to insulate the second electrode 105 which is formed later from the first electrode 102, thereby avoiding the short-circuit of the second electrode 105 and the first electrode 102.

The protective layer 104 is prepared by the CVD process. The protective layer 104 acquired by the CVD process has a strong gap penetrating capability, and can effectively fill the gap between the target particle a and the light-emitting layer 103.

The thickness of the first portion 1041 of the protective layer 104 in the direction perpendicular to the base substrate 101 ranges from 2 nm to 5 nm, that is, the protective layer 104 is not too thick or too thin. Therefore, the protective layer 104 can have an insulating effect, and can also facilitate the injection of electrons generated by the second electrode 105 into the light-emitting layer 103 through tunneling to ensure the effective light emission of the display panel 1.

In some embodiments, the inorganic material is at least one of silicon oxide, silicon nitride, and silicon nitride oxide.

In step S405, a second electrode is formed on a side of the protective layer away from the base substrate.

In the embodiments of the present disclosure, for the detailed description of step S405, reference can be referred to step S207 described above, and the details are not repeated herein.

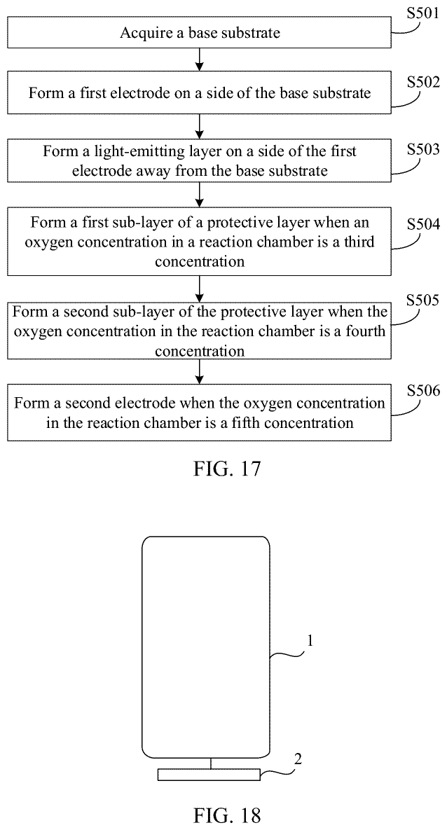

FIG. 17 is a flowchart of still another method for preparing a display panel according to some embodiments of the present disclosure. Referring to FIG. 17, the method the following steps.

In step S501, a base substrate is acquired.

In step S502, a first electrode is formed on a side of the base substrate.

In step S503, a light-emitting layer is formed on a side of the first electrode away from the base substrate.

In the embodiments of the present disclosure, for the detailed description of steps S501 to S503, reference can be referred to steps S201 to S203 described above, and the details are not repeated herein.

In step S504, a first sub-layer of a protective layer is formed when an oxygen concentration in a reaction chamber is a third concentration.

In the embodiments of the present disclosure, the film layers of the display panel 1 are all prepared in the reaction chamber. Due to the increase of the oxygen concentration in the reaction chamber, the impedance of the prepared film layer increases. Therefore, in order to acquire the first sub-layer m1 with a lower impedance, the third concentration is made lower, in some embodiments, less than 1 sccm.

Since the first sub-layer m1 has a lower impedance and is in direct contact with the electron transport layer in the light-emitting layer 103, the transport effect of the electrons generated by the second electrode 105 can be ensured.

In some embodiments, the first sub-layer m1 is made of IZO, ZnOx or InOx, and the first sub-layer m1 is prepared by a sputtering process or an ALD process.

In step S505, a second sub-layer of the protective layer is formed when the oxygen concentration in the reaction chamber is a fourth concentration.

The thickness of the first sub-layer m1 formed in the above step S504 ranges from 50 A to 100 A, that is, the first sub-layer m1 is relatively thin and does not fill up the gap between the target particle a and the light-emitting layer 103. Thus, by providing the second sub-layer m2 with higher impedance on the side of the first sub-layer m1 away from the base substrate 101, the second sub-layer m2 with higher impedance fills up the gap, which can avoid the short-circuit of the second electrode 105 and the first electrode 102. In this implementation, the portion of the first sub-layer m1 and the portion of the second sub-layer m2 which fill the gap form the first portion 1041 of the protective layer 104, and the portion of the first sub-layer m1 and the portion of the second sub-layer m2 which are outside the gap form the second portion 1042 of the protective layer 104.

In this implementation, the impedance of the second sub-layer m2 is greater than an impedance threshold. The impedance of the second sub-layer m2 being greater than the impedance threshold refers to that the surface resistance of the protective layer 104 is greater than the ninth powers of ten (10⁹).

Referring to FIG. 5, with the increase of the oxygen concentration in the reaction chamber, the impedance of the acquired film layer increases. Thus, in order to acquire the second sub-layer m2 with higher impedance, the most direct method is to increase the oxygen concentration in the reaction chamber. Increasing the oxygen concentration in the reaction chamber makes the second sub-layer m2 have fewer oxygen vacancies during film formation, which can increase the impedance of the second sub-layer m2.

In some embodiments, the second sub-layer m2 of the protective layer 104 is formed when the oxygen concentration in the reaction chamber is the fourth concentration. The fourth concentration is greater than the third concentration, in some embodiments, the fourth concentration is greater than 4 sccm.

In some embodiments, the second sub-layer m2 is made of IZO, ZnOx or InOx, and the second sub-layer m2 is prepared by a sputtering process or an ALD process.

In step S506, a second electrode is formed when the oxygen concentration in the reaction chamber is a fifth concentration.

In embodiments of the present disclosure, when the second electrode 105 is prepared, the oxygen concentration in the reaction chamber is lower (the fifth concentration is less than the fourth concentration), in some embodiments, less than 1 sccm.

The second electrode 105 is a cathode of a light-emitting element in the display panel 1. The second electrode 105 is made of IZO. In some embodiments, the second electrode 105 is prepared by a sputtering process, an ALD process, or the like.

In some embodiments, the display panel 1 includes a plurality of light-emitting elements, and the cathodes of the plurality of light-emitting elements are a common film layer.

In summary, the embodiments of the present disclosure provide a method for preparing a display panel. The display panel prepared by this method includes a base substrate, and a first electrode, a light-emitting layer, a protective layer, and a second electrode which are sequentially laminated on a side of the base substrate. Due to the influence of the preparation process of the display panel, a target particle is easily embedded in the light-emitting layer, and a gap in communication with the side of the light-emitting layer away from the base substrate is formed between the embedded target particle and the light-emitting layer. The first portion of the protective layer which is insulated from the first electrode and the second electrode fills the gap, which can prevent the formed second electrode from penetrating to the first electrode along the gap, and thus can avoid the short-circuit of the first electrode and the second electrode. Therefore, the yield of the display panel and the display effect of the display device are ensured.

FIG. 18 is a schematic structural diagram of a display device according to some embodiments of the present disclosure. Referring to FIG. 18, the display device includes a power supply assembly 2, and the display panel 1 as provided in the above embodiments. The power supply assembly 2 is configured to supply power to the display panel 1.

In some embodiments, the display device may be any other product or component having a display function, such as a liquid crystal display (LCD), an organic light-emitting diode (OLED) display device, electronic paper, a low temperature poly-silicon (LTPS) display device, a low temperature poly-silicon oxide (LTPO) display device, an oxide display device, a mobile phone, a tablet computer, a television, a display, a laptop, a digital photo frame, and a navigator

Since the display device has substantially the same technical effects as the display panel 1 described in the foregoing embodiments, the technical effects of the display panel 1 are not repeated here for the purpose of brevity.

The above descriptions are merely optional embodiments of the present disclosure, and are not intended to limit the present disclosure. Any modifications, equivalent substitutions, improvements and the like made within the spirit and principles of the present disclosure shall be included within the protection scope of the present disclosure.

1. A display panel, wherein the display panel comprises: a base substrate, and a first electrode, a light-emitting layer, a protective layer, and a second electrode which are sequentially laminated on a side of the base substrate; wherein
a side of the light-emitting layer away from the base substrate is embedded with a target particle, and a gap in communication with the side of the light-emitting layer away from the base substrate is defined between the light-emitting layer and the target particle; and
the protective layer at least comprises a first portion insulated from both the first electrode and the second electrode, wherein the first portion fills the gap.

2. The display panel according to claim 1, wherein the target particle protrudes from a surface of the light-emitting layer away from the base substrate, and for a portion of the target particle which is embedded in the light-emitting layer, an orthographic projection of a side of the portion close to the base substrate onto the base substrate is within an orthographic projection of a side of the portion away from the base substrate onto the base substrate; and the protective layer further comprises a second portion outside the gap;
the first portion is made of an oxide of a first material, and the second portion is made of a second material; and the first material is unable to be evaporated on the second material.

3. The display panel according to claim 2, wherein the first material is magnesium and the second material is hydroxyquinolinolato-lithium.

4. The display panel according to claim 1, wherein the protective layer further comprises a second portion outside the gap; wherein
the second portion and the first portion are an integral structure.

5. The display panel according to claim 4, wherein a number of oxygen vacancies in the protective layer is less than a number of oxygen vacancies in the second electrode.

6. The display panel according to claim 5, wherein a film layer density of the protective layer is greater than a film layer density of the second electrode.

7. The display panel according to claim 4, wherein the first portion and the second portion are both made of an inorganic material.

8. The display panel according to claim 7, wherein a thickness of the first portion in a direction perpendicular to the base substrate ranges from 2 nm to 5 nm.

9. The display panel according to claim 7, wherein the inorganic material is at least one of silicon oxide, silicon nitride, and silicon nitride oxide.

10. The display panel according to claim 4, wherein the first portion and the second portion of the protective layer both comprise a first sub-layer and a second sub-layer which are sequentially laminated in a direction going away from the base substrate; wherein
impedance of the second sub-layer is greater than impedance of the first sub-layer and is greater than impedance of the second electrode.

11. The display panel according to claim 10, wherein a number of oxygen vacancies in the second sub-layer is less than a number of oxygen vacancies in the first sub-layer and is less than a number of oxygen vacancies in the second electrode.

12. The display panel according to claim 10, wherein a film layer density of the second sub-layer is greater than a film layer density of the second electrode and is greater than a film layer density of the first sub-layer.

13. A method for preparing a display panel, comprising:
acquiring a base substrate; and
forming a first electrode, a light-emitting layer, a protective layer, and a second electrode sequentially on a side of the base substrate;
wherein a side of the light-emitting layer away from the base substrate is embedded with a target particle, and a gap in communication with the side of the light-emitting layer away from the base substrate is defined between the light-emitting layer and the target particle; and
wherein the protective layer at least comprises a first portion insulated from both the first electrode and the second electrode, wherein the first portion fills the gap.

14. The method according to claim 13, wherein the target particle protrudes from a surface of the light-emitting layer away from the base substrate, and for a portion of the target particle which is embedded in the light-emitting layer, an orthographic projection of a side of the portion close to the base substrate onto the base substrate is within an orthographic projection of a side of the portion away from the base substrate onto the base substrate; and forming the protective layer comprises:
evaporating a second material on the side of the light-emitting layer away from the base substrate to form a second portion of the protective layer, wherein the second portion fractures at the gap;
evaporating a first material in the gap; and
performing an oxidation treatment on the first material to acquire the first portion of the protective layer;
wherein the second material is unable to be evaporated in a region where the first material is formed.

15. The method according to claim 13, wherein forming the protective layer and the second electrode comprises:
forming the first portion and a second portion of the protective layer when an oxygen concentration in a reaction chamber is a first concentration, wherein the second portion is outside the gap; and
forming the second electrode when the oxygen concentration in the reaction chamber is a second concentration;
wherein the first concentration is greater than the second concentration.

16. The method according to claim 15, wherein the first concentration is greater than 4 volume flow rates, and the second concentration is less than 1 volume flow rate.

17. The method according to claim 13, wherein forming the protective layer comprises:
forming the first portion and a second portion of the protective layer by using an inorganic material on the side of the light-emitting layer away from the base substrate, wherein the second portion is outside the gap.

18. The method according to claim 13, wherein forming the protective layer and the second electrode comprises:
forming a first sub-layer when an oxygen concentration in a reaction chamber is a third concentration;
forming a second sub-layer when the oxygen concentration in the reaction chamber is a fourth concentration, wherein a portion of the second sub-layer and a portion of the first sub-layer which fill the gap form the first portion of the protective layer, and a portion of the second sub-layer and a portion of the first sub-layer which are outside the gap form a second portion of the protective layer; and
forming the second electrode when the oxygen concentration in the reaction chamber is a fifth concentration;
wherein the fourth concentration is greater than the third concentration and is greater than the fifth concentration.

19. The method according to claim 18, wherein the third concentration and the fifth concentration are both less than 1 volume flow rate, and the fourth concentration is greater than 4 volume flow rates.

20. A display device, comprising: a power supply assembly, and a display panel; wherein
the power supply assembly is configured to supply power to the display panel; and
the display panel comprises: a base substrate, and a first electrode, a light-emitting layer, a protective layer, and a second electrode which are sequentially laminated on a side of the base substrate; wherein
a side of the light-emitting layer away from the base substrate is embedded with a target particle, and a gap in communication with the side of the light-emitting layer away from the base substrate is defined between the light-emitting layer and the target particle; and
the protective layer at least comprises a first portion insulated from both the first electrode and the second electrode, wherein the first portion fills the gap.
